(19) United States
(12) Patent Application Publication
(10) Pub. No.: US 2011/0058952 A1
(43) Pub. Date: Mar. 10, 2011

(54) HIGH-TEMPERATURE ANTI-CORROSIVE LAYER AND METHOD FOR THE PRODUCTION THEREOF

(75) Inventors: Horst Pillhoefer, Roehrmoos (DE); Markus Niedermeier, Muenchen (DE); Siegfried Seuss, Muenchen (DE)

(73) Assignee: MTU Aero Engines GmbH, Munich (DE)

(21) Appl. No.: 12/877,018

(22) Filed: Sep. 7, 2010

Related U.S. Application Data
(60) Provisional application No. 61/240,337, filed on Sep. 8, 2009.

(51) Int. Cl. F01D 5/28; C23C 16/44; C23C 16/06; F01D 5/14

(52) U.S. Cl. 416/241 R; 427/248.1; 427/250

(57) ABSTRACT

A method for producing a high-temperature protective layer containing metal on a metallic high-temperature material is disclosed. The metal is deposited on the high-temperature material via the gaseous phase to form the high-temperature protective layer. The high-temperature material is held at a diffusion temperature for a specific length of time so that at least a portion of the deposited metal is diffused into the high temperature material to form a diffusion zone and where the high-temperature material is not in contact with solids or liquids in the region of the surface to be coated, but merely has a solid/gas interface. Also disclosed is a component made of a high-temperature material with a hot-gas anti-corrosive layer containing chromium. There is a coating layer containing chromium applied to the surface of the high-temperature material, a diffusion layer in the high-temperature material, and a build-up zone between the coating layer and the diffusion layer.

This application claims the benefit of U.S. Provisional Application No. 61/240,337, filed Sep. 8, 2009, the disclosure of which is expressly incorporated by reference herein.

### BACKGROUND AND SUMMARY OF THE INVENTION

The present invention relates to a method for producing a high-temperature protective layer containing metal on a metallic high-temperature material, in which the metal is deposited on the high-temperature material via the gaseous phase to form the high-temperature protective layer and wherein the high-temperature material is held at a diffusion temperature for a specific length of time so that at least a portion of the deposited metal is diffused in the high-temperature material to form a diffusion zone. The invention also relates to a correspondingly produced component made of a high-temperature material with a hot-gas anti-corrosive layer, which contains chromium in particular.

Oxidation protection layers or hot-gas anti-corrosive layers for protecting metallic materials that are used at high temperatures are known from the prior art. For example, the layers are described in Protective Oxide Scales and their Breakdown, by Michael Schütze, John Wiley & Sons Ltd., Chichester, New York, Weinheim, Brisbane, Singapore, Toronto (ISBN: 0-471-95904-9).

Layers containing chromium and aluminum in particular are used here, because they form slow-growing chromium oxide or aluminum oxide layers. To form chromium layers it is known to form these as diffusion layers, wherein first of all chromium is deposited electrolytically or via the gaseous phase in a powder packing in order to subsequently diffuse into the material to be protected.

A corresponding method is also described in international application WO 2006/076013 A2, in which turbine blades are coated by a chromium diffusion method.

In this method, the component to be coated is packed in a powder packing of the so-called donor metal, wherein an activator is also contained in the powder packing and a neutral filling material may also be provided to avoid agglomerations of the powder. For the most part, the activator is a halogen compound, in particular a chlorine compound, which is highly volatile and which assumes the transport of the donor material to the surface being coating so that the material is deposited there.

Although it is already possible to generate satisfactory protective layers with such a chromalizing method, a disadvantage of the method is that the developing layers are often very brittle and it is difficult to control the coating process.

Therefore, the object of the present invention is making available a high-temperature protective layer and a method for the production thereof, in particular for high-temperature materials, which is used with turbine blades and in particular aircraft turbines. The high-temperature layer or the hot-gas anti-corrosive layer should hereby avoid the disadvantages of the prior art and have in particular good mechanical properties with respect to fatigue strength and ductility. The corresponding method should be easy to control and regulate, and be simple to use.

The invention starts from the knowledge that an improvement of deposition from the gaseous phase known from the prior art in a powder packing may be achieved to the effect that the component to be coated is not embedded in the powder packing, but arranged at a distance from the donor metal so that a pure deposition via the gaseous phase takes place, wherein the to-be-coated surface of the high-temperature material is not in contact with solids or liquids, but merely has a solid/gas interface. Every deposition via the gaseous phase is correspondingly conceivable, regardless of how the gaseous phase is produced.

At the same time, the diffusion of the metallic protective layer components into the high-temperature material is assured via a corresponding heating.

By separating the surface to be coated from the donor metal, an improved control of the coating process is possible and the deposited layer is more ductile.

Deposition via the gaseous phase is possible in particular if, according to the known methods with donor metal particles and an activator, the donor metal particles or the activator are held at a distance from the to-be-coated surface of the high-temperature material. The distance in this case may be in particular 0.1 to 100 mm, preferably 0.5 to 50 mm. The donor metal powder in this case may be present in a filling in the vicinity of the surface being treated.

The filling of the donor metal powder may have a density which comprises an 80% packing density or less, in particular a 70% packing density or less, in order to make an adequately large surface possible for the reaction of the donor metal with the activator.

The donor metal powder may be correspondingly benefited with an average or maximum particle size of 2 mm or greater, in particular 3 mm or greater, which in-turn favors making an adequate reaction surface of the donor metal available.

The method is carried out at a process temperature, at which, on the one hand, a diffusion of the deposited metal into the high-temperature material takes place and, on the other hand, with the use of a corresponding chemical vapor deposition method (CVD) with donor metal powder and activator, an adequate transport of the metal to be deposited takes place. To that effect, the activator is preferably selected such that at the process temperature or diffusion temperature, the activator has a vapor pressure of 0.1 to 600 mbar, preferably 0.5 to 500 mbar.

The method, which is carried out with the exclusion of reactive gases such as oxygen and the like, in a vacuum chamber or comparable reaction chamber, also provides that the corresponding reaction chamber be flushed before and/or after the coating and/or during a pure diffusion phase and namely in particular with an inert or noble gas, preferably argon.

As a result, a flushing before and/or after the surface treatment allows, firstly, a corresponding purity and cleanliness to be guaranteed, and secondly for a two-stage treatment method to be used. In the case of the two-stage method, a first process step may be provided in which both a deposition of metal for the high-temperature protective layer is carried out and at the same time the diffusion of the deposited metal into the high-temperature material takes place. In a second step of the process, merely a corresponding diffusion of the previously deposited metal may take place so that the quantity of the deposited material and/or the diffusion depth may be adjusted in a targeted manner. In contrast to the methods according to the prior art, the method according to the invention thus offers the possibility of having a targeted impact on the deposition and/or diffusion via a corresponding flushing of the pure gas compartment without interfering powder packings on the surface to be coated, because the deposition of additional material may be stopped by a change in the pure gas atmosphere, while the diffusion of the deposited material into the high-temperature material may be continued.

The process temperature, at which both the deposition as well as the diffusion is carried out and which is therefore also designated as the diffusion temperature, may lie in a range of 900° C. to 1200° C., in particular 1100° C. to 1150° C. and most preferably in a range of 1130° C. to 1135° C. The holding time, also designated as the diffusion time, i.e., the time during which the high-temperature material is kept at the diffusion temperature, may be between 2 hours and 15 hours, in particular 4 hours to 8 hours.

In the case of a two-stage method, the pure diffusion phase, i.e., during which no deposition of additional material takes, may be 1/10 to 1/15 of the entire holding time, in particular 1/12 of the entire holding time, i.e., in particular one quarter of an hour to three quarters of an hour, preferably approximately one half hour.

The method may preferably be carried out in a two-shelled apparatus, wherein an outer chamber provided around the reaction chamber may have a lower pressure so that due to the excess pressure merely gas may escape from the reaction chamber, but no impurities may end up in the reaction chambers.

The method according to the invention may be used in particular for the deposition of a protective chromium layer and namely on corresponding nickel-based alloys for turbine blades. Correspondingly, the donor material may be chromium powder, wherein the activator may be a compound containing halogen, in particular containing chlorine, in particular a chloride or a halide of a constituent of the high-temperature material or of the metal to be deposited. Accordingly, nickel chlorides, cobalt chlorides, aluminum chlorides or chromium chloride may be used.

In addition to the described method with the use of a donor metal powder with activator, it is also conceivable for corresponding gas containing metal to be introduced directly into the reaction area for deposition on the high-temperature material.

The method according to the invention may be used to form a ductile gradient protective layer on a chromium basis, which has a coating layer, an inwardly directed diffusion layer and a build-up zone arranged between the diffusion and coating layer, wherein the chromium content of the build-up zone lies between that of the diffusion layer and the coating layer.

The coating layer may have in particular the modification of α-chromium and a chromium content of 25 to 90% by weight, in particular 30 to 80% by weight. The thickness of the coating layer may be selected in a range of 0.1 to 20 in particular 0.2 to 15 μm. The build-up zone may have a chromium content of 15 to 40% by weight and in particular of 20 to 30% by weight as well as a thickness of 2 to 75 μm, in particular of 5 to 50 μm. The diffusion layer, which may have a chromium content of 5 to 30% by weight, in particular of 10 to 20% by weight, may also have a thickness of 2 to 75 μm, in particular of 5 to 50 μm. Turbine blades on the basis of nickel-based alloys that are provided with such a high-temperature anti-corrosive protective layer have a hot-gas corrosion resistance which is better by the factor of 10 than the base material, wherein the fatigue strength in the low-load and high-load areas decreases only negligibly for example.

Additional advantages, characteristics and features of the present invention will become clear in the subsequent detailed description of the exemplary embodiments on the basis of the drawings. In this case, the drawings show the following in a purely schematic manner.

### BRIEF DESCRIPTION OF THE DRAWINGS

FIG. 1 illustrates an apparatus for carrying out the coating method; and

FIG. 2 is a sectional view through a portion of a material surface having the high-temperature protective coating according to the invention.

### DETAILED DESCRIPTION OF THE DRAWINGS

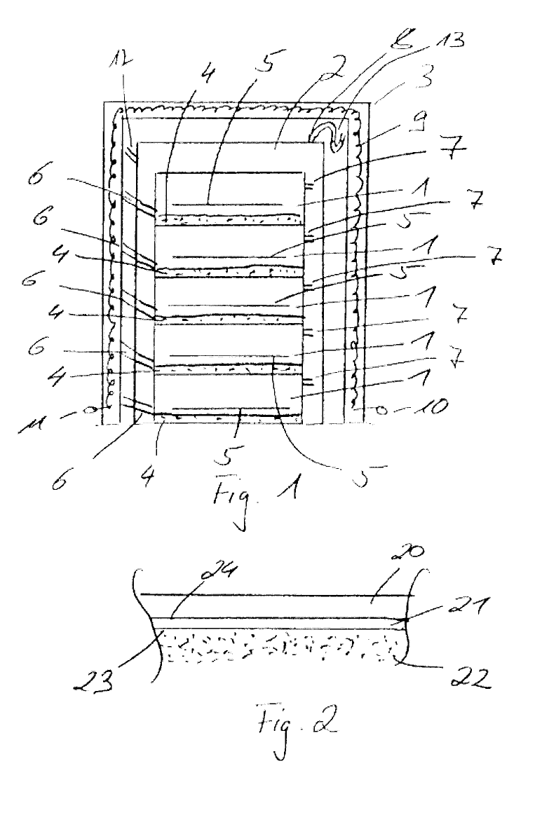

FIG. 1 shows a purely schematic depiction of an apparatus for carrying out the coating method according to the invention. The apparatus includes five process chambers 1, which are configured identically and housed stacked on top of each other in a reaction area 2, a so-called retorting vessel. The reaction area 2 is surrounded in turn by a hood-type furnace 3, by means of which the corresponding process temperature or diffusion temperature may be adjusted. To this end, the hood-type furnace 3 has, for example, an electric resistance heater 9, which features electrical connectors 10 and 11.

The process chambers 1 each have a gas supply 6, which are supplied with gas by a central gas supply (not shown in greater detail). The gas supply 6 in this case is arranged at the reaction chambers 1 such that a gas flow directed into the reaction chamber 1 is aimed at a powder bed 4 arranged at the bottom of the reaction chamber 1. The powder bed 4 features the donor metal or the donor metal alloy, such as, for example, chromium or a chromium alloy, which coats the components 5 in the reaction chambers 1. Because the gas supplies 6 are directed at the powder bed 4, this may be flushed with a gas flow in an effective manner.

The reaction chambers 1 also have gas outlets 7, which are depicted merely schematically in the representation in FIG. 1. The gas outlet 7 may be configured in a variety of ways as a non-return valve or as a semi-permeable seal, i.e., a seal with a flow direction, thereby guaranteeing that merely gas may escape from the reaction chambers 1, but no additional gas may end up therein. As a result, it is guaranteed that corresponding reaction products may be removed from the chamber when flushing the reaction chambers 1 and a clean atmosphere may be adjusted therein.

In addition, the reaction area 2 (retorting vessel) also has a gas inlet 12 as well as a gas outlet 8, which is connected with a gas scrubber 13, for example.

Operation is carried out such that first a corresponding powder of a donor metal or a donor metal alloy, for example a chromium powder, is introduced into the individual reaction chambers 1. In addition, an activator is uniformly distributed on the loose filling of the donor metal powder, in which there may be a maximum density of 70% or 80% space utilization. The activator may be, for example, a halogen compound, in particular a chloride of the donor metal or a chloride of the high-temperature material that is to be coated. In the case of a nickel-based alloy, which features, for example, nickel, cobalt, aluminum and the like, nickel chlorides, cobalt chlorides, aluminum chlorides, chromium chlorides and the like may be used, for example.

The to-be-coated component 5 is arranged in the vicinity of the filling or the powder bed 4, wherein a distance of the to-be-coated surface from the powder bed 4 is set in the order of magnitude of 0.5 to 50 mm. The correspondingly arranged reaction chambers 1, which are sealed by a cover, for example, are then stacked on top of each other so they can be housed in the reaction area (retorting vessel) 2. The entire structure of reaction chambers 1 stacked on top of each other, which are arranged in the reaction area 2, is surrounded by the hood-type furnace 3 so that by heating the hood-type furnace 3, the materials located in the powder bed 4 as well as the to-be-coated component 5 are heated. Through the heating process, the metal halides or metal chlorides become volatile and cause the corresponding metal components, i.e., the donor metal, to be transported to the surface of the component 5 where the donor metal is correspondingly deposited. The releasing halogen or chlorine reacts in-turn with the donor metal, e.g., chromium, thereby conveying the donor metal onto the surface of the component 5.

The process temperature is selected is such a way that the donor metal may diffuse into the component 5, for example in the case of a chromalizing of nickel-based alloy used for turbine blades, a temperature in a range of 1100 to 1150° C., in particular 1130 to 1135° C. In the case of this process temperature, which may also be designated as the diffusion temperature, the to-be-coated component 5 as well as the materials located in the process chambers 1 are kept for a specific treatment time, which is in a range of 3 to 7 hours, in particular 3.75 to 6.25 hours and most preferably in a range of 5 to 6 hours.

The coating process here may be selected to be two-stage, in that during the second portion of the coating process, only a diffusion of the deposited metal into the component is rendered possible, while an additional deposition is prevented. To this end, an inert gas such as, for example, argon, is injected into the reaction chamber 1 via the gas supplies 6 of the reaction chambers 1 so that the halogen compounds, which are required for transporting the donor metal to the surface of the component, are flushed out via the gas exits 7 that are permeable in only one direction. Through an additional flushing of the reaction area 2 via the gas inlet 12 and the gas outlet 8, the reaction gases are also removed from the reaction area 2, wherein a cleaning of the exhaust gas takes place via the gas scrubber 13. Thus, only the diffusion is still maintained during the second portion of the treatment process, because the process temperature or diffusion temperature is maintained. The second portion of the treatment may be approximately 1/10 to 1/15 of the entire holding duration, preferably 1/12 of the holding duration, wherein the holding duration is the period of time during which the desired diffusion temperature is achieved in the reaction chamber 1. Due to the two-stage process with, on the one hand, simultaneous deposition and diffusion of the layer material during the first portion of the process, and, on the other hand, the process segment during which merely a diffusion takes place, the quantity of deposited material, and therefore, the thickness of the deposited layer may be varied and adjusted. At the same time, by adjusting the relationship between the process step during which material is deposited and material is diffused into the component and the process step during which only a diffusion takes place, it is possible to adjust the relationship between a correspondingly produced coating layer and a diffusion zone as well as a build-up zone being formed in-between.

Furthermore, the flushing with an inert gas allows very clean surfaces to generate and reduces the danger that residues containing halogen, in particular those containing chlorine, are contained in the reaction chamber.

During the entire method, the reaction area 2 may be flushed with an inert gas, such as argon, in order to purge exiting process gases from the reaction chambers 1. In this connection, however, the pressure is kept lower in the reaction area 2 than in the reaction chambers 1 in order to allow only a gas flow from the reaction chambers 1 into the reaction area 2.

During the heating phase or during the holding time at the process temperature or the diffusion temperature during the active process phase, i.e., the first step of the process with simultaneous deposition and diffusion, there is no flushing with inert gas in the reaction chambers 1. This does not start until the so-called passive stage of the process step, i.e., diffusion without additional material deposition, is supposed to take place. In addition, the flushing with inert gas in the process chambers 1 is also maintained during the cooling phase, wherein, however, similarly to in the reaction area 2, with a correspondingly decreasing temperature, the flushing quantity may be reduced.

The method may be executed in particular such that the flush rate is adjusted so that at the end of the process, a 10 to 1000-times exchange of the process chamber volume or of the powder bed volume takes place.

Using the corresponding procedure, it is possible to form a normal three-zone protective layer on the component, which is made of up a coating layer 20, a build-up zone 21, and a diffusion layer 22, as FIG. 2 shows. The coating layer in terms of the chromalizing according to the invention is a layer in the modification of the α-chromium, wherein the chromium content may vary between 25 and 80% by weight. The layer thickness may be between 0.2 μm and 15 μm.

The build-up zone 21 has a lower chromium content in a range of 15 to 30% by weight chromium as well as a layer thickness of between 5 μm and 50 μm.

The internal chromium diffusion layer 22 has the lowest chromium content in a range of 5 to 20% by weight with a layer thickness of 5 μm to 50 μm.

Although the interfaces 23 and 24 between the individual layers are depicted as distinct lines in the schematic representation of FIG. 2, it is self-evident for the person skilled in the art that these transitions do not have to be sharp and discrete, rather are present as gradual, continuous transitions. In particular, the chromium content may reduce continuously from the outside inwardly so that a gradient layer is configured.

In addition to the deposited chromium, elements from the material of the component to be coated, for example nickel, cobalt, aluminum and the like, may be present in the coating layer 20 in particular.

It turns out that such a layer structure on a high-temperature material, such as for example, a nickel-based super alloy for turbine blades, produces a distinct improvement of the hot-gas corrosion resistance, while the likewise important mechanical property with respect to the fatigue strength only deteriorates negligibly both in the range of low load cycles as well as high load cycles.

Correspondingly, the present invention is characterized especially, but not exclusively, by the following embodiments:

1. Method for producing a high-temperature protective layer containing metal on a metallic high-temperature material (5), in which the metal is deposited on the high-temperature material via the gaseous phase to form the high-temperature protective layer, wherein the high-temperature material is held at a diffusion temperature for a specific length of time so that at least a portion of the deposited metal is diffused into the high-temperature material to form a diffusion zone, in which the high-temperature material is not in contact with solids or liquids in the region of the surface to be coated, but merely has a solid/gas interface.

2. Method according to Embodiment 1, in which donor metal particles and an activator are heated to a temperature so that the donor metal is deposited on the high-temperature material via volatile compounds of the donor metal with the activator, wherein the donor metal is arranged at a distance from the high-temperature material to be coated.

3. Method according to Embodiment 2, in which the distance between the donor metal particles and material surface to be coated is 0.1 to 200 mm.

4. Method according to Embodiment 2, in which the distance between the donor metal particles and material surface to be coated is 0.5 to 50 mm.

5. Method according to one of the Embodiments 2 to 4, in which the donor metal particles are present in a filling (4) with a density of 70% packing density or less.

6. Method according to one of the Embodiments 2 to 4, in which the donor metal particles are present in filling (4) with a density of 60% packing density or less.

7. Method according to one of the Embodiments 2 to 6, in which the donor metal particles are present with an average or minimum particle size of 2 mm or more.

8. Method according to one of the Embodiments 2 to 6, in which the donor metal particles are present with an average or maximum particle size of 3 mm or more.

9. Method according to one of the preceding embodiments, in which the activator has a vapor pressure of 0.1 to 600 mbar at the diffusion temperature.

10. Method according to one of the preceding embodiments, in which the activator has a vapor pressure of 0.5 to 500 mbar at the diffusion temperature.

11. Method according to one of the preceding embodiments, in which the method is carried out in a reaction chamber (1), which makes it possible for the reaction chamber to be flushed before and/or after the coating and/or during a pure diffusion phase.

12. Method according to Embodiment 11, in which the flushing of the reaction chamber is carried out with inert or noble gas, in particular argon.

13. Method according to one of the preceding embodiments, in which a two-stage process is conducted, wherein in a first step a deposition of metal of the high-temperature protective layer and diffusion of the metal in the high-temperature material is carried out, while in a second step the previously deposited metal is essentially merely diffused into the high-temperature material.

14. Method according to one of the preceding embodiments, in which the diffusion temperature is 900° C. to 1200° C.

15. Method according to one of the preceding embodiments, in which the diffusion temperature is 1050° C. to 1160° C.

16. Method according to one of the preceding embodiments, in which the diffusion temperature is 1130° C. to 1135° C.

17. Method according to one of the preceding embodiments, in which the holding time during the diffusion temperature is between 2 hrs and 16 hrs.

18. Method according to one of the preceding embodiments, in which the holding time during the diffusion temperature is between 4 hrs and 8 hrs, in particular between 5 hrs and 6 hrs.

19. Method according to Embodiment 13 and one of the Embodiments 17 or 18, in which the second step is 1/10 to 1/15, in particular 1/12 of the overall holding time.

20. Method according to one of the preceding embodiments, in which along with the reaction chamber (1), an additional outer chamber (2) is used so that there is a two-shelled housing, wherein the outer chamber is kept at a pressure that is lower than that of the reaction chamber.

21. Method according to Embodiment 20, in which the outer chamber is flushed with an inert or noble gas during the entire process.

22. Method according to one of the preceding embodiments, in which the metal to be deposited is chromium or an alloy containing chromium.

23. Method according to one of the preceding embodiments, in which the high-temperature material is a Ni-based alloy and/or a turbine blade material.

24. Method according to one of the Embodiments 2 to 23, in which the activator is a compound containing chlorine, in particular a chloride, a constituent of the high-temperature material or of the material to be deposited.

25. Method according to Embodiment 1, in which the metal to be deposited is introduced gaseously into a reactor for deposition on the high-temperature material.

26. Component made of a high-temperature material with a hot-gas anti-corrosive layer, which contains chromium, in which there is a coating layer (20) containing chromium applied to the surface of the high-temperature material, a diffusion layer (22) in the high-temperature material and a build-up zone (21) between the coating layer and the diffusion layer, the chromium content of the zone being between that of the diffusion layer and the coating layer.

27. Component according to Embodiment 26, in which the coating layer (20) is present in the modification of α-chromium.

28. Component according to Embodiment 26 or 27, in which the coating layer (20) has a chromium content of 25 to 90% by weight.

29. Component according to one of the Embodiments 26 to 28, in which the coating layer (20) has a chromium content of 30 to 80% by weight.

30. Component according to one of the Embodiments 26 to 29, in which the coating layer (20) has a thickness of 0.1 to 20 μm.

31. Component according to one of the Embodiments 26 to 29, in which the coating layer (20) has a thickness of 0.2 to 15 μm.

32. Component according to one of the Embodiments 26 to 31, in which the build-up zone (21) has a chromium content of 15 to 40% by weight.

33. Component according to one of the Embodiments 26 to 32, in which the build-up zone (21) has a chromium content of 20 to 30% by weight.

34. Component according to one of the Embodiments 26 to 33, in which the build-up zone (21) has a thickness of 2 to 75 μm.

35. Component according to one of the Embodiments 26 to 33, in which the build-up zone (21) has a thickness of 5 to 50 μm.

36. Component according to one of the Embodiments 26 to 35, in which the diffusion layer (22) has a chromium content of 5 to 30% by weight.

37. Component according to one of the Embodiments 26 to 35, in which the diffusion layer (22) has a chromium content of 10 to 20% by weight.

38. Component according to one of the Embodiments 26 to 37, in which the diffusion layer (22) has a thickness of 2 to 75 μm.

39. Component according to one of the Embodiments 26 to 38, in which the diffusion layer (22) has a thickness of 5 to 50 μm.

40. Component according to one of the Embodiments 26 to 39, in which the high-temperature material is a Ni-based alloy and/or a turbine blade material.

41. Component according to one of the Embodiments 26 to 40, in which the component is a turbine blade.

Although the present invention was described in detail on the basis of the exemplary embodiments, it is self-evident for the person skilled in the art that the invention is not restricted to these exemplary embodiments, but that modifications are in fact possible, for example in the form of a different combination of individual features or by the omission of an individual feature, without leaving the scope of protection of the enclosed claims. The present invention includes in particular all combinations of all presented features.

What is claimed is:

1. A method for producing a high-temperature protective layer containing metal on a metallic high-temperature material, comprising the steps of:
depositing the metal on the high-temperature material via a gaseous phase to form the high-temperature protective layer, wherein the high-temperature material is held at a diffusion temperature for a specific length of time so that at least a portion of the deposited metal is diffused into the high-temperature material to form a diffusion zone;
wherein the high-temperature material is not in contact with solids or liquids in a region of a surface to be coated such that the high-temperature material only has a solid/gas interface.

2. The method according to claim 1, wherein donor metal particles and an activator are heated to a temperature so that the donor metal is deposited on the high-temperature material via volatile compounds of the donor metal with the activator, wherein the donor metal is arranged at a distance from the high-temperature material to be coated.

3. The method according to claim 2, wherein the distance is 0.1 to 200 mm.

4. The method according to claim 2, wherein the donor metal particles are present in a filling with a density of 70% packing density or less and/or the donor metal particles are present with an average or minimum particle size of 2 mm or more.

5. The method according to claim 2, wherein the activator has a vapor pressure of 0.1 to 600 mbar at the diffusion temperature.

6. The method according to claim 1, wherein the method is carried out in a reaction chamber, wherein the reaction chamber is flushed before and/or after a coating phase and/or during a pure diffusion phase, and wherein the flushing of the reaction chamber is carried out with inert or noble gas.

7. The method according to claim 1, wherein a two-stage process is conducted, wherein in a first step a deposition of metal of the high-temperature protective layer and diffusion of the metal in the high-temperature material is carried out, while in a second step the previously deposited metal is diffused into the high-temperature material.

8. The method according to claim 7, wherein the diffusion temperature is 900° C. to 1200° C. and/or the holding time at the diffusion temperature is between 2 hours and 16 hours and wherein the second step is 1/10 to 1/15 of an overall holding time.

9. The method according to claim 6, wherein along with the reaction chamber, an additional outer chamber is used so that there is a two-shelled housing, wherein the outer chamber is kept at a pressure that is lower than that of the reaction chamber, and wherein the outer chamber is flushed with an inert or noble gas during an entire process.

10. The method according to claim 1, wherein the metal to be deposited is chromium or an alloy containing chromium and the high-temperature material is a Ni-based alloy and/or a turbine blade material.

11. The method according to claim 2, wherein the activator is a compound containing chlorine.

12. The method according to claim 1, wherein the metal to be deposited is introduced gaseously into a reactor for deposition on the high-temperature material.

13. A component made of a high-temperature material with a hot-gas anti-corrosive layer, which contains chromium, comprising:
a coating layer containing chromium applied to a surface of the high-temperature material;
a diffusion layer in the high-temperature material; and
a build-up zone between the coating layer and the diffusion layer, wherein a chromium content of the zone is between a chromium content of the diffusion layer and the coating layer.

14. The component according to claim 13, wherein the coating layer is present in a modification of a-chromium.

15. The component according to claim 13, wherein the coating layer has a chromium content of 25 to 90% by weight and/or a thickness of 0.1 to 20 μm.

16. The component according to claim 13, wherein the build-up zone has a chromium content of 15 to 40% by weight and/or a thickness of 2 to 75 μm.

17. The component according to claim 13, wherein the diffusion layer has a chromium content of 5 to 30% by weight and/or a thickness of 2 to 75 μm.

18. The component according to claim 13, wherein the high-temperature material is a Ni-based alloy and/or a turbine blade material and/or the component is a turbine blade.
